(19) United States
(12) Patent Application Publication
(10) Pub. No.: US 2004/0087094 A1
(43) Pub. Date: May 6, 2004

(54) Semiconductor component and method of manufacture

(75) Inventors: Derick Wristers, Bee Cave, TX (US); Chad Weintraub, Dresden (DE); James F. Buller, Austin, TX (US); Jon Cheek, Austin, TX (US)

Correspondence Address: Rennie Dover, The Cavanagh Law Firm, Ste. 2400, 1850 N. Central Avenue, Phoenix, AZ, 85004, US

(73) Assignee: ADVANCED MICRO DEVICES, INC.

(21) Appl. No.: 10/284,654

(22) Filed: Oct. 30, 2002

(51) Int. Cl. H01L 21/336; H01L 21/425

(52) U.S. Cl. 438/302; 438/305; 438/525

(57) ABSTRACT

An insulated gate field effect transistor having differentially doped source-side and drain-side halo regions and a method for manufacturing the transistor. A gate structure is formed on a major surface of a semiconductor substrate. A source-side halo region is proximal the source extension region and a drain-side halo region is proximal the drain extension region, where the drain-side halo region has a higher dopant concentration than the source-side halo region. A source extension region and a drain extension region are formed in a semiconductor material. The source extension region extends under a gate structure, whereas the drain extension region may extend under the gate structure or be laterally spaced apart from the gate structure or be aligned to the gate side adjacent the drain region. A source region is adjacent the source extension region and a drain region is adjacent the drain extension region.

### FIELD OF THE INVENTION

This invention relates, in general, to semiconductor components and, more particularly, to channel doping in an insulated gate semiconductor component.

### BACKGROUND OF THE INVENTION

Integrated circuits such as microprocessors, digital signal processors, microcontrollers, memory devices, and the like typically contain millions of Insulated Gate Field Effect Transistors (IGFETs). Because of the desire to lower manufacturing costs and increase circuit speed, integrated circuit manufacturers shrink the sizes of the IGFET's making up an integrated circuit so that more integrated circuits can be manufactured from a single semiconductor wafer. Although the smaller transistors are capable of operating at increased speeds, secondary performance factors such as decreased source-drain breakdown voltage, increased junction capacitance, and instability of the threshold voltage negatively affect transistor performance. Collectively, these adverse performance effects are referred to as short channel effects.

Typical techniques for mitigating short channel effects rely on adjusting the electric field in the channel region to minimize the peak lateral electric field of the drain depletion region. One technique for lowering the lateral electric field is to include source and drain extension regions. A source extension region extends into a silicon substrate adjacent one side of a gate structure and a drain extension region extends into the silicon substrate adjacent an opposing side of the gate structure. The source and drain extension regions extend under the gate structure, which increases the overlap between the gate structure and the source and drain extension regions. The increased overlap in the drain region increases the drain-side Miller capacitance and the gate-to-drain tunneling current, thereby decreasing the performance of the transistor.

Accordingly, what is needed is a semiconductor component having reduced overlap between the gate structure and the drain-side extension region and a method for manufacturing the semiconductor component.

### SUMMARY OF THE INVENTION

The present invention satisfies the foregoing need by providing a semiconductor component and a method for manufacturing the semiconductor component having asymmetric source-side and drain-side halo region doping concentrations. In accordance with one aspect, the present invention comprises a method for manufacturing the semiconductor component wherein a gate structure is formed on a semiconductor material of the first conductivity type. Dopant concentrations of the first conductivity type are differentially increased in a portion of the semiconductor material proximal the first side of the gate structure and in a portion of the semiconductor material proximal the second side of the gate structure. The dopant concentration in the portion of the semiconductor material proximal the second side of the gate structure is greater than the dopant concentration in the portion of the semiconductor material proximal the first side of the gate structure. A doped region of a second conductivity type is formed in the semiconductor material proximal the first side of the gate structure and another doped region of the second conductivity type is formed in the semiconductor material proximal the second side of the gate structure.

In accordance with another aspect, the present invention includes forming source and drain extension regions in addition to the differentially doped halo regions. In one embodiment, the source and drain extension regions are formed by implanting a dopant of a second conductivity type into the semiconductor material at an angle of less than 90 degrees with respect to a direction perpendicular to a major surface of the semiconductor material. After implantation, a portion of the dopant is proximal one side of the gate structure and extends into the semiconductor material under the gate structure and another portion of the dopant is proximal an opposing side of the gate structure and may be laterally spaced apart from the opposing side of the gate structure or it may extend under the gate structure from the opposing side or it may be aligned to the opposing side of the gate structure. In another embodiment, the source and drain extension regions are formed by implanting the dopant of the second conductivity type using a zero degree implant.

In accordance with another aspect, the present invention comprises an insulated gate field effect transistor comprising a semiconductor substrate including a gate structure having source and drain sides formed thereon. A source-side halo region is proximal the source side of the gate structure and a drain-side halo region is proximal the drain side of the gate structure. A dopant concentration of the drain-side halo region is greater than a dopant concentration of the source-side halo region. A source extension region is adjacent the source side of the gate structure and extends under the gate structure and a drain extension region is adjacent the second side of the gate structure and may be laterally spaced apart from the drain side of the gate structure or it may extend under the gate structure from the drain side or it may be aligned to the drain side of the gate structure. A source region is adjacent to and spaced apart from the source side of the gate structure and a drain region is adjacent to and spaced apart from the drain side of the gate structure.

### BRIEF DESCRIPTION OF THE DRAWINGS

The present invention will be better understood from a reading of the following detailed description, taken in conjunction with the accompanying drawing figures in which like references designate like elements and in which:

FIGS. 1-8 are highly enlarged cross-sectional views of a portion of an insulated gate semiconductor component in accordance with an embodiment of the present invention; and

FIGS. 9-12 are highly enlarged cross-sectional views of a portion of an insulated gate semiconductor component in accordance with another embodiment of the present invention.

### DETAILED DESCRIPTION

Generally, the present invention provides a method for manufacturing a semiconductor component such as an insulated gate semiconductor device or field effect transistor. An insulated gate semiconductor device is also referred to as insulated gate field effect transistor, a field effect transistor, a semiconductor component, or a semiconductor device. In accordance with an embodiment of the present invention, differentially doped source-side and drain-side halo regions are formed wherein the dopant concentration of the drain-side halo region is greater than the dopant concentration of the source-side halo region. In accordance with another embodiment of the present invention, an insulated gate field effect transistor has asymmetric source and drain extension regions and differentially doped source-side and drain-side halo regions, where the dopant concentration of the drain-side halo region is greater than the dopant concentration of the source-side halo region.

In yet another embodiment of the present invention, an insulated gate field effect transistor has symmetric source and drain extension regions and differentially doped source-side and drain-side halo regions, where the dopant concentration of the drain-side halo region is greater than the dopant concentration of the source-side halo region. Forming the halo regions such that the drain-side halo region has a higher dopant concentration than the source-side halo region reduces: the overlap of the drain extension region by the gate structure, the drain-side Miller capacitance, and the drain-to-gate direct tunneling current. The reduction in the drain-side Miller capacitance beneficially reduces the overall output capacitance appearing at an output node of a driver circuit such as, for example, a CMOS inverter. Asymmetric source and drain extension regions also reduce the overlap between the drain extension region and the gate structure, thereby reducing the direct gate-to-drain tunneling current.

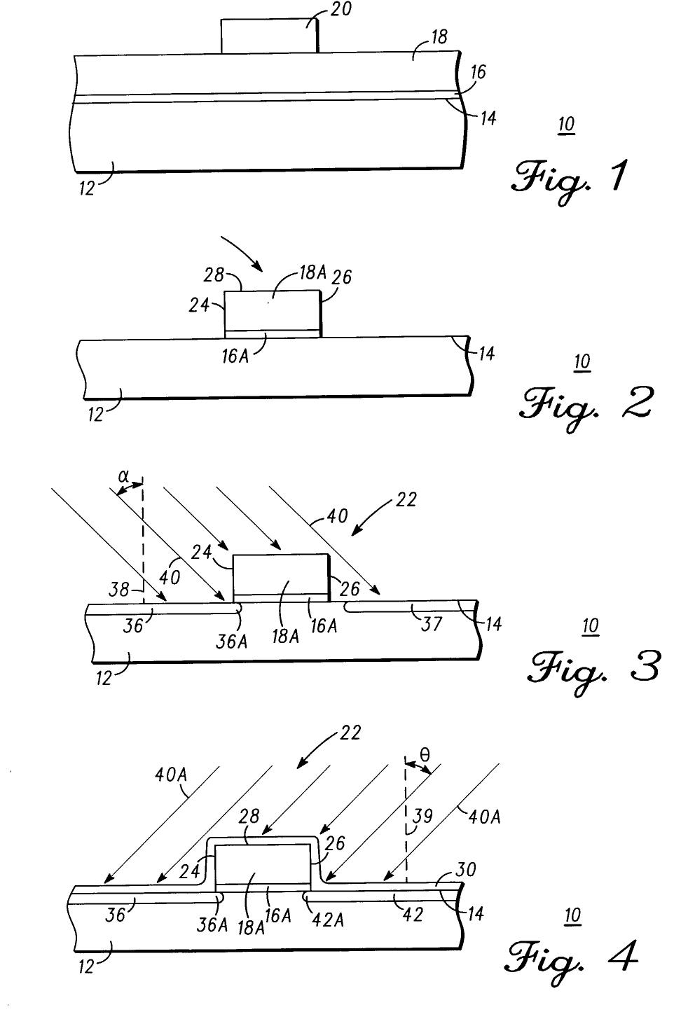

FIG. 1 is an enlarged cross-sectional view of a portion of a partially completed insulated gate field effect transistor 10 during beginning processing steps in accordance with an embodiment of the present invention. What is shown in FIG. 1 is a semiconductor substrate 12 of P-type conductivity having a major surface 14. By way of example, semiconductor substrate 12 is silicon having a <100> crystal orientation and a concentration of P-type dopants on the order of 1×10¹⁶ ions per cubic centimeter (ions/cm³). Alternatively, semiconductor substrate 12 may be comprised of a heavily doped silicon wafer having a <100> crystal orientation and a lightly doped epitaxial layer disposed thereon. Other suitable materials for substrate 12 include silicon germanium, germanium, Silicon-On-Insulator (SOI), and the like. The conductivity type of substrate 12 is not a limitation of the present invention. In accordance with the present embodiment, the conductivity type is chosen to form an N-channel insulated gate field effect transistor. However, the conductivity type of the substrate can be selected to form a P-channel insulated gate field effect transistor or a complementary insulated gate field effect transistor, e.g., a Complementary Metal Oxide Semiconductor (CMOS) transistor. In addition, dopant wells such as an N-well in a substrate of P-type conductivity or a P-well in a substrate of N-type conductivity can be formed in substrate 12. The P-channel and N-channel field effect transistors are formed in the respective dopant wells. Although not shown, it should be understood that a threshold voltage adjust implant may be performed in semiconductor substrate 12 or in the dopant wells.

A layer of dielectric material 16 is formed on major surface 14. Dielectric layer 16 serves as a gate dielectric material and may be formed by techniques known to those skilled in the art including thermal oxidation, chemical vapor deposition, and the like. Layer 16 has a thickness ranging from approximately 15 Angstroms (Å) to approximately 500 Å. A layer of polysilicon 18 is formed on dielectric layer 16 using, for example, a chemical vapor deposition technique. A suitable range of thicknesses for polysilicon layer 18 is between approximately 500 Å and approximately 2,000 Å. By way of example, dielectric layer 16 has a thickness of 200 Å and polysilicon layer 18 has a thickness of 1,500 Å. A layer of photoresist (not shown) is deposited on polysilicon layer 18 and patterned to form an etch mask 20. Techniques for depositing and patterning photoresist are well known to those skilled in the art.

Referring now to FIG. 2, polysilicon layer 18 is etched using an etch chemistry that preferentially etches polysilicon. By way of example, polysilicon layer 18 is etched using anisotropic Reactive Ion Etching (RIE). Methods for etching polysilicon are well known to those skilled in the art. After removal of the exposed portions of polysilicon layer 18, the etch chemistry is changed to anisotropically etch oxide layer 16. The anisotropic etching of oxide layer 16 stops at major surface 14. Then etch mask layer 20 is removed. The remaining portions 18A and 16A of polysilicon layer 18 and dielectric layer 16, respectively, form a gate structure 22 having sides 24 and 26 and a top surface 28. Portion 18A serves as a gate conductor and portion 16A serves as a gate oxide or gate dielectric.

Referring now to FIG. 3, a dopant of P-type conductivity such as, for example, boron or indium, is implanted into semiconductor material 12 to form doped regions 36 and 37. A portion 36A of doped region 36 is referred to as a source-side halo region. Preferably, the implant is an angled or tilt angle implant which makes an angle α with respect to a direction (indicated broken lines 38) substantially perpendicular (or normal) to major surface 14, wherein angle α is less than 90 degrees and preferably ranges from approximately 20 degrees to approximately 65 degrees. Even more preferably, angle α ranges between approximately 35 degrees and approximately 45 degrees. A suitable set of parameters for the halo implant includes implanting the dopant of P-type conductivity at a dose ranging between approximately 1×10¹² ions/cm² and approximately 1×10¹⁵ ions/cm² and using an implant energy ranging between approximately 100 electron Volts (eV) and approximately 50 kilo electron Volts (keV). The angled dopant implantation is represented by arrows 40. The implant energy and implant dose are exemplary values for forming an N-channel insulated gate field effect transistor and are not limitations of the present invention. As those skilled in the art are aware, the implant energy and implant dose for a P-channel insulated gate field effect transistor may be different from those for an N-channel insulated gate field effect transistor. For example, a suitable implant energy for forming a halo region in an P-channel insulated gate field effect transistor may range from approximately 1 keV to approximately 100 keV. Because semiconductor component 10 includes a source-side halo region and a drain-side halo region, the drain side of semiconductor component 10 is not masked during the formation of doped region 36. Thus, this implantation step introduces dopants into the portion of semiconductor material 12 that is on the drain side of semiconductor component 10 and spaced apart from gate side 26.

Referring now to FIG. 4, semiconductor substrate 12 is rotated through 180 degrees in an ion implant apparatus (not shown) and the dopant of P-type conductivity is implanted into semiconductor material 12 to form doped region 42. Rotation of semiconductor substrate 12 is referred to as twisting the substrate; hence, performing an implant, rotating substrate 12, and performing another implant is typically referred to as a two twist implant. A portion 42A of doped region 42 is also called a drain-side halo region. Preferably, the implant is an angled or tilt angle implant, which makes an angle θ with respect to a direction (indicated by broken lines 39) substantially perpendicular to major surface 14, wherein angle θ is less than 90 degrees and preferably ranges from approximately 20 degrees to approximately 65 degrees. Even more preferably, angle θ ranges between approximately 35 degrees and approximately 45 degrees. A suitable set of parameters for the halo implant includes implanting the dopant of P-type conductivity at a dose ranging between approximately 1×10¹³ ions/cm² and approximately 1×10¹⁶ ions/cm² and using an implant energy ranging between approximately 100 electron Volts (eV) and approximately 50 kilo electron Volts (keV). The angled dopant implantation is represented by arrows 40A. The dose for forming drain-side halo region 42A is preferably selected to be greater than that for forming source-side halo region 36A, thus the dopant concentration of drain-side halo region 42A is greater than the dopant concentration of source-side halo region 36A. In other words, the source-side and drain-side halo regions are differentially doped such that the dopant concentration of the drain-side halo region is greater than that of the source-side halo region. Preferably, the dopant concentration of the drain-side halo region is between about 1.5 to 5 times greater than the dopant concentration of the source-side halo region. Even more preferably, the dopant concentration of the drain-side halo region is between about 1.5 to 10 times greater than the dopant concentration of the source-side halo region. The implant energy and implant dose are exemplary values for forming an N-channel insulated gate field effect transistor and are not limitations of the present invention. As those skilled in the art are aware, the implant energy and implant dose for a P-channel insulated gate field effect transistor may be different from those for an N-channel insulated gate field effect transistor. Because semiconductor component 10 includes a source-side halo region and a drain-side halo region, the source side of semiconductor component 10 is not masked during the formation of doped region 42. Thus, this implantation step introduces dopants into semiconductor material 12 on the source side of semiconductor component 10; however, it should be understood gate structure 22 blocks the drain-side halo implant from doping source-side halo region 36A. It should be further understood that although gate structure 22 may be doped by the halo implants, the doping concentration is sufficiently low as to not adversely affect performance of semiconductor component 10. For the sake of clarity, the doped region on the source side of semiconductor component 10 is identified by reference number 36 and the doped region on the drain side of semiconductor component 10 is identified by reference number 42, where portion 36A serves as the source-side halo region and portion 42A serves as the drain-side halo region. The concentration of dopant in drain-side halo region 42A is greater than that in source-side halo region 36A, which results in the gate-drain overlap capacitance being less than the source-drain overlap capacitance. This lowers the capacitance at the output node of a CMOS inverter, which results in a reduced capacitance on the output node when a load circuit is coupled thereto.

Semiconductor component 10 may be annealed using a rapid thermal anneal (RTA) process or a conventional furnace anneal process. By way of example, semiconductor component 10 is annealed by heating to a temperature ranging between approximately 800 degrees Celsius (° C.) and approximately 1,100° C. Annealing semiconductor component 10 causes the dopant to diffuse in both the vertical and lateral directions. Using an angled implant to form the source-side halo region and the drain-side halo region positions the halo regions towards the center of the channel region.

Still referring to FIG. 4, a layer of dielectric material 30 is deposited on gate structure 22 and the exposed portions of major surface 14. By way of example, layer of dielectric material 30 is oxide having a thickness ranging between approximately 50 Å and approximately 1,500 Å.

Referring now to FIG. 5, oxide layer 30 is anisotropically etched to form spacers 32 and 34 and to expose major surface 14. An extension implant is performed to form a source extension region 48 and a drain extension region 52. The extension implant also dopes gate structure 22. Source extension region 48 is formed in semiconductor material 12 adjacent side 24 of gate structure 22 and a drain extension region 52 is formed in semiconductor material 12 adjacent side 26 of gate structure 22. A suitable set of parameters for forming source and drain extension regions 48 and 52, respectively, includes implanting an N-type dopant such as, for example, arsenic using a zero degree implant (indicated by arrows 50) at a dose ranging between approximately 1×10¹⁴ ions/cm² and approximately 1×10¹⁶ ions/cm² and an implant energy ranging between approximately 100 electron Volts and approximately 20 keV. The energy and dose are exemplary values and are not limitations of the present invention. Semiconductor component 10 may be annealed using a rapid thermal anneal (RTA) process or a conventional furnace anneal process. By way of example, semiconductor component 10 is annealed by heating to a temperature ranging between approximately 800° C. and approximately 1,100° C. Annealing semiconductor component 10 causes the dopant of source and drain extension regions 48 and 52, respectively, to diffuse in both the vertical and lateral directions. Likewise, the anneal step causes the dopant of source-side halo region 36A and drain-side halo region 42A to diffuse in both the vertical and lateral directions.

Still referring to FIG. 5, a silicon nitride layer 55 is deposited on gate structure 22, spacers 32 and 34, and the exposed portions of major surface 14. By way of example, silicon nitride layer 55 is deposited using a chemical vapor deposition technique. Preferably, silicon nitride layer 55 has a thickness ranging between approximately 200 Å and approximately 1,500 Å. Alternatively, layer 55 can be an oxide layer or a layer of any material suitable for forming spacers.

Referring now to FIG. 6, silicon nitride layer 55 is anisotropically etched to form nitride spacers 44 and 46 and to expose major surface 14 of semiconductor substrate 12. Thus, spacer 32 is between spacer 44 and side 24 of gate structure 22 and spacer 34 is between spacer 46 and side 26 of gate structure 22. A source/drain implant is performed to form a source region 53 and a drain region 54. The source/drain implant also dopes gate structure 22. A suitable set of parameters for the source/drain implant includes implanting an N-type dopant such as, for example, phosphorus at a dose ranging between approximately 1×10¹⁴ ions/cm² and approximately 1×10¹⁶ ions/cm² and an implant energy ranging between approximately 5 keV and approximately 100 keV. The doped semiconductor material is annealed by heating to a temperature between approximately 800° C. and 1,100° C. It should be understood that an implant screening mask may be formed over semiconductor component 10 prior to performing the source-side and drain-side halo implants, the source and drain extension implant, and the source and drain implant. However, this screening mask has not been shown for the sake of clarity.

A layer of refractory metal 60 is deposited on top surface 28, spacers 44 and 46, and the exposed portions of silicon surface 14. By way of example, the refractory metal is cobalt having a thickness ranging between approximately 50 Å and approximately 300 Å.

Referring now to FIG. 7, the refractory metal layer is heated to a temperature ranging between 600° C. and 700° C. The heat treatment causes the cobalt to react with the silicon to form cobalt silicide (CoSi₂) in all regions in which the cobalt is in contact with silicon. Thus, cobalt silicide 56 is formed from gate 18A, cobalt silicide 58 is formed from source region 53, and cobalt silicide 62 is formed from drain region 54. The portions of the cobalt disposed on spacers 44 and 46 remain unreacted. It should be understood that the type of suicide is not a limitation of the present invention. For example, other suitable silicides include titanium silicide (TiSi), platinum silicide (PtSi), nickel silicide (NiSi), and the like. As those skilled in the art are aware, silicon is consumed during the formation of silicide and the amount of silicon consumed is a function of the type of silicide being formed.

Still referring to FIG. 7, the unreacted cobalt is removed using processes known to those skilled in the art. Removing the unreacted cobalt electrically isolates gate 18A, source region 53, and drain region 54 from each other.

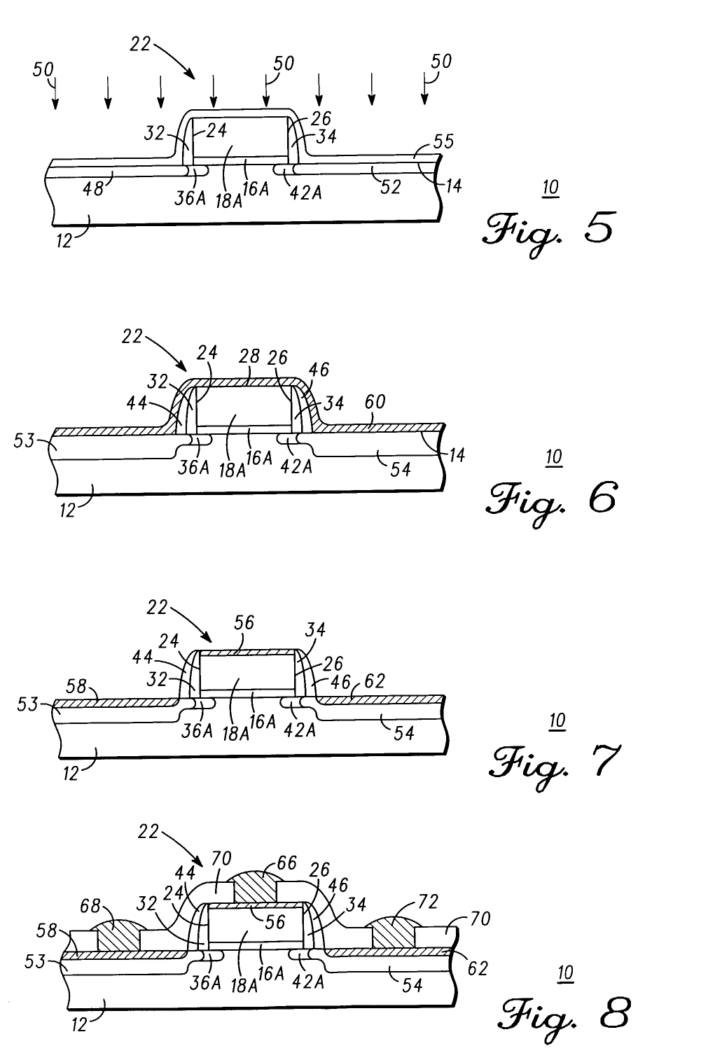

Referring now to FIG. 8, a layer of dielectric material 70 is formed on the structure including the silicided regions. By way of example, dielectric material 70 is oxide having a thickness ranging between approximately 5,000 Å and approximately 15,000 Å. Openings are formed in oxide layer 70 to expose portions of silicide layers 56, 58, and 62. Using techniques well known in the art, electrical conductors or electrodes are formed which contact the exposed silicide layers 56, 58, and 62. More particularly, a gate electrode 66 contacts gate silicide 56, a source electrode 68 contacts source silicide layer 58, and a drain electrode 72 contacts drain silicide layer 62. Thus, in accordance with this embodiment, semiconductor component 10 has differentially doped source-side and drain-side extension regions and symmetrically positioned source and drain extension regions.

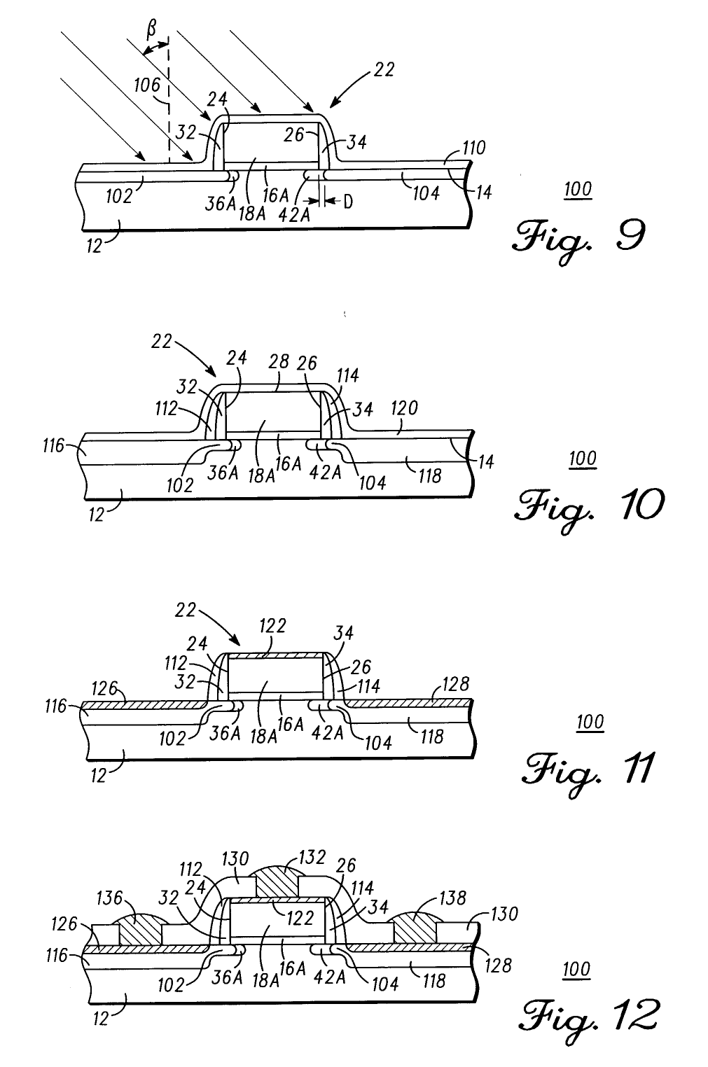

FIG. 9 is an enlarged cross-sectional side view of a semiconductor component 100 in accordance with another embodiment of the present invention. It should be understood that the beginning processing steps in the manufacture of semiconductor component 100 are the same as those described with reference to FIGS. 1-4. It should be noted that the semiconductor component in the embodiment of FIGS. 9-12 is identified by reference number 100. Accordingly, in the present invention FIG. 9 continues from FIG. 4. What is shown in FIG. 9, is semiconductor component 100 comprising semiconductor material 12 having gate structure 22 formed thereon, source-side halo region 36A adjacent side 24 of gate structure 22 and drain-side halo region 42A adjacent side 26 of gate structure 22. Oxide layer 30 is anisotropically etched to form spacers 32 and 34 and to expose major surface 14. An extension implant is performed to form a source extension region 102 and a drain extension region 104. The extension implant also dopes gate structure 22. Source extension region 102 is formed in semiconductor material 12 adjacent side 24 of gate structure 22, and a drain extension region 104 is formed in semiconductor material 12 adjacent side 26 of gate structure 22. A suitable set of parameters for forming source and drain extension regions 102 and 104, respectively, includes implanting an N-type dopant such as, for example, arsenic at an angle β with respect to a direction (indicated by broken lines 106) substantially perpendicular (or normal) to major surface 14, wherein the angle β ranges between approximately 0 degrees and approximately 20 degrees. A suitable implant dose ranges between approximately 1×10¹⁴ ions/cm² and approximately 1×10¹⁶ ions/cm² and a suitable implant energy ranges between approximately 100 electron Volts and approximately 20 keV. The energy and dose are exemplary values and are not limitations of the present invention. The implant may be annealed using a rapid thermal anneal (RTA) process or a conventional furnace anneal process. By way of example, semiconductor component 100 is annealed by heating to a temperature ranging between approximately 800° C. and approximately 1,100° C. Annealing semiconductor component 100 causes the dopant of source and drain extension regions 102 and 104, respectively, to diffuse in both the vertical and lateral directions. Likewise, the anneal causes the dopant of source-side halo region 36A and drain-side halo region 42A to diffuse in both the vertical and lateral directions.

Because source and drain extension regions 102 and 104, respectively, are formed using an angled or tilt angle implant, they are asymmetric about structure 22. Source extension region 102 extends into semiconductor substrate 12 and under gate structure 22 from side 24, whereas drain extension region 104 extends into semiconductor substrate 12 and may extend under gate structure 22 or be laterally spaced apart from side 26 of gate structure 22 or be aligned to gate side 26. The distance D between drain extension region 104 and side 26 of gate structure 22 is dependent, in part, upon the implantation angle. For example, drain extension region 104 is about 40 Å from side 26 when implantation angle β is about 10 degrees, whereas drain extension region 104 is about 80 Å from side 26 when implantation angle β is about 20 degrees. In addition, the anneal process and the height of gate structure 22 affect the distance between drain extension region 104 and side 26. The higher the anneal temperature and the longer the time of the anneal, the closer drain extension region 104 diffuses towards side 26.

Still referring to FIG. 9, a silicon nitride layer 110 is deposited on gate structure 22, spacers 32 and 34, and the exposed portions of major surface 14. By way of example, silicon nitride layer 110 is deposited using a chemical vapor deposition technique. Preferably, silicon nitride layer 10 has a thickness ranging between approximately 200 Å and approximately 1,500 Å. Alternatively, layer 110 can be an oxide layer or a layer of any material suitable for forming spacers.

Referring now to FIG. 10, silicon nitride layer 110 is anisotropically etched to form nitride spacers 112 and 114 and to expose major surface 14 of semiconductor substrate 12. Thus, spacer 32 is between spacer 112 and side 24 of gate structure 22 and spacer 34 is between spacer 114 and side 26 of gate structure 22.

A source/drain implant is performed to form a source region 116 and a drain region 118. The source/drain implant also dopes gate structure 22. A suitable set of parameters for the source/drain implant includes implanting an N-type dopant such as, for example, phosphorus at a dose ranging between approximately 1×10¹⁴ ions/cm² and approximately 1×10¹⁶ ions/cm² and using an implant energy ranging between approximately 5 keV and approximately 100 keV. The doped semiconductor material is annealed by heating to a temperature between approximately 800° C. and 1,100° C.

Still referring to FIG. 10, an optional wet etch is performed to remove any oxide along top surface 28 of gate 18A and any oxide layer disposed on major surface 14. A layer of refractory metal 120 is conformally deposited on top surface 28, spacers 112 and 114, and the exposed portions of silicon surface 14. By way of example, the refractory metal layer is cobalt having a thickness ranging between approximately 50 Å and 300 Å.

Referring now to FIG. 11, the refractory metal layer is heated to a temperature ranging between 600° C. and 700° C. The heat treatment causes the cobalt to react with the silicon to form cobalt silicide (CoSi₂) in all regions in which the cobalt is in contact with silicon. Thus, cobalt silicide 122 is formed from gate 18A, cobalt silicide 126 is formed from source region 116, and cobalt silicide 128 is formed from drain region 118. The portions of the cobalt disposed on spacers 112 and 114 remain unreacted. It should be understood that the type of silicide is not a limitation of the present invention. For example, other suitable silicides include titanium silicide (TiSi), platinum silicide (PtSi), nickel silicide (NiSi), and the like. As those skilled in the art are aware, silicon is consumed during the formation of silicide and the amount of silicon consumed is a function of the type of silicide being formed.

Still referring to FIG. 11, the unreacted cobalt is removed using processes known to those skilled in the art. Removing the unreacted cobalt electrically isolates gate 18A, source region 116, and drain region 118 from each other.

Referring now to FIG. 12, a layer of dielectric material 130 is formed on the structure including the silicided regions. By way of example, dielectric material 130 is oxide having a thickness ranging between approximately 5,000 Å and approximately 15,000 Å. Openings are formed in oxide layer 130 to expose portions of silicide layers 122, 126, and 128. Using techniques that are well known to those skilled in the art, electrical conductors or electrodes are formed which contact the exposed silicide layers 122, 126, and 128. More particularly, a gate electrode 132 contacts gate silicide 122, a source electrode 136 contacts source silicide layer 126, and a drain electrode 138 contacts drain silicide layer 128. Thus, in accordance with this embodiment, semiconductor component 100 has differentially doped source-side and drain-side halo regions and asymmetrically positioned source and drain extension regions.

By now it should be appreciated that an insulated gate semiconductor component and a method for manufacturing the semiconductor component have been provided. In accordance with one aspect of the present invention, the drain-side halo region has a higher dopant concentration than the source-side halo region. In other words, the halo regions are differentially doped. The higher dopant concentration of the drain-side halo regions reduces the overlap between the gate structure and the drain side of the semiconductor component. This is advantageous because it reduces the drain-side Miller capacitance and the drain-to-gate direct tunneling current.

In accordance with another aspect, the present invention includes asymmetric source and drain extension regions, where the source extension region extends under the gate structure and the drain extension region may extend under the gate structure, be aligned to one edge of the gate structure, or be laterally spaced apart from the gate structure or be aligned to the gate side proximal the drain region. Forming the source extension region under the gate structure (i.e., increasing the overlap of the gate structure with the source-side extension region) lowers the source-side resistance of the semiconductor component and increases the gate to source voltage, thereby providing more drive current. This improves the DC performance of the semiconductor component. In addition, reducing or eliminating the overlap of the gate structure with the drain-side extension region reduces the drain-side Miller capacitance which improves the AC performance of the semiconductor component. Further, decreasing the overlap of the gate structure with the drain-side extension region reduces the gate-to-drain direct tunneling current.

Although certain preferred embodiments and methods have been disclosed herein, it will be apparent from the foregoing disclosure to those skilled in the art that variations and modifications of such embodiments and methods may be made without departing from the spirit and scope of the invention. For example, the semiconductor component may have a source extension region but not a drain extension region or a drain extension region but not a source extension region.

What is claimed is:

1. A method for manufacturing a semiconductor component, comprising:
providing a semiconductor material of a first conductivity type having a major surface;
forming a gate structure on the major surface, the gate structure having first and second sides and a top surface;
differentially increasing dopant concentrations of the first conductivity type in first and second portions of the semiconductor material, the first portion proximal the first side of the gate structure and the second portion proximal the second side of the gate structure; and
forming first and second doped regions of a second conductivity type in the semiconductor material, the first doped region proximal to the first side of the gate structure and to the first portion of the semiconductor material and the second doped region proximal to the second side of the gate structure and to the second portion of the semiconductor material.

2. The method of claim 1, wherein differentially increasing dopant concentrations of the first conductivity type comprises implanting a dopant of the first conductivity type into the semiconductor material using an angled implant that makes an angle less than 90 degrees relative to a direction perpendicular to the major surface.

3. The method of claim 2, wherein implanting comprises implanting at an angle between 20 degrees and 65 degrees.

4. The method of claim 1, wherein forming the first and second doped regions comprises forming a first spacer adjacent the first side of the gate structure and a second spacer adjacent the second side of the gate structure and implanting a dopant of the second conductivity type into the semiconductor material.

5. The method of claim 4, wherein implanting the dopant includes implanting at an angle that is zero degrees relative to a line that is normal to the major surface.

6. The method of claim 1, wherein differentially increasing dopant concentrations of the first conductivity type includes increasing a dopant concentration of the second portion to a greater concentration than a dopant concentration of the first portion.

7. The method of claim 1, wherein the dopant concentration of the second portion is from 1.5 to 10 times greater than the dopant concentration of the first portion.

8. The method of claim 7, further including forming a third doped region, the third doped region of the second conductivity, adjacent the first doped region, and of a lower concentration than the first doped region.

9. The method of claim 8, further including forming a fourth doped region, the fourth doped region of the second conductivity type, adjacent the second doped region, and of a lower concentration than the second doped region.

10. A method for manufacturing a semiconductor device, comprising:
providing a semiconductor material of a first conductivity type and having a major surface;
forming a gate structure on the semiconductor material, the gate structure having first and second sides and a top surface;
forming a source-side halo region of the first conductivity type adjacent the first side of the gate structure and a drain-side halo region of the first conductivity type adjacent the second side of the gate structure, wherein a concentration of the drain-side halo region is greater than a concentration of the source-side halo region; and
forming a source and drain regions of a second conductivity type in the semiconductor material, the source region adjacent the source-side halo region and the drain region adjacent the drain-side halo region.

11. The method of claim 10, wherein forming the source-side halo region comprises implanting a dopant at a first dose into a portion of the semiconductor material proximal the first side of the gate structure and forming the drain-side halo region comprises implanting the dopant at a second dose into a portion of the semiconductor material proximal the second side of the gate structure.

12. The method of claim 11, wherein forming the source-side and drain-side halo regions comprises implanting the dopant at the first dose using an angled implant and implanting the dopant at the second dose using another angled implant.

13. The method of claim 10, further including forming a source extension region in the semiconductor material, the source extension region adjacent the first portion of the semiconductor material.

14. The method of claim 13, further including forming a drain extension region in the semiconductor material, the drain extension region adjacent the second portion of the semiconductor material.

15. The method of claim 10, further including forming a drain extension region in the semiconductor material, the drain extension region adjacent the second portion of the semiconductor material.

16. The method of claim 15, further including forming the drain extension region by implanting a dopant into the semiconductor material using an angled implant.

17. A semiconductor component, comprising:
a semiconductor material of a first conductivity type having a major surface;
a gate structure having first and second sides disposed on the major surface;
a source-side halo region proximal the first side of the gate structure and a drain-side halo region proximal the second side of the gate structure, a concentration of the drain-side halo region greater than a concentration of the source-side halo region; and
a source region in the semiconductor material proximal the first side of the gate structure and a drain region in the semiconductor material proximal the second side of the gate structure.

18. The semiconductor component of claim 17, further including a drain extension region in the semiconductor material, the drain extension region adjacent the drain region.

19. The semiconductor component of claim 18, wherein the drain extension region extends under the gate structure.

20. The semiconductor component of claim 17, further including a source extension region in the semiconductor material, the source extension region adjacent the source region.

21. The semiconductor component of claim 17, further including a first spacer adjacent the first side of the gate structure and a second spacer adjacent the second side of the gate structure, wherein the source region is aligned to the first spacer and the drain region is aligned to the second spacer.

22. The semiconductor component of claim 21, wherein the source-side halo region extends under the gate structure from the source region and the drain-side halo region extends under the gate structure from the drain region.
